(19) United States
(12) Patent Application Publication
(10) Pub. No.: US 2025/0133924 A1
(43) Pub. Date: Apr. 24, 2025

(54) DISPLAY PANEL

(71) Applicant: Samsung Display Co., Ltd., Yongin-si (KR)

(72) Inventors: Junseok Min, Yongin-si (KR); Dongjin Moon, Yongin-si (KR); Kyungsu Lee, Yongin-si (KR)

(21) Appl. No.: 18/662,682

(22) Filed: May 13, 2024

(30) Foreign Application Priority Data
Oct. 23, 2023 (KR) 10-2023-0142351

(51) Int. Cl. H10K 59/131; H10K 59/80

(52) U.S. Cl. CPC H10K 59/131; H10K 59/873

(57) ABSTRACT

A display panel including: a substrate having an opening region, a display region, and a middle region between the opening region and the display region; a plurality of display elements in the display region; an encapsulation layer covering the plurality of display elements and extending from the display region to the middle region; a planarization layer in the middle region and overlapping a portion of the encapsulation layer; a crack sensing portion on the planarization layer and extending around a portion of the opening region; and a cover layer covering a first end of the planarization layer that is on the encapsulation layer and electrically connected to the crack sensing portion.

### CROSS-REFERENCE TO RELATED APPLICATION

The present application claims priority to and the benefit of Korean Patent Application No. 10-2023-0142351, filed on Oct. 23, 2023, in the Korean Intellectual Property Office, the entire disclosure of which is incorporated herein by reference.

### BACKGROUND

### 1. Field

Aspects of embodiments of the present disclosure relate to a display panel.

### 2. Description of the Related Art

Recently, applications of display apparatuses have diversified. In addition, display apparatuses are manufactured to be thinner and lighter, thereby allowing for a wider range of uses.

As the area occupied by a display region in a display apparatus has been expanded, various functions that are incorporated or linked to the display apparatus have been added to the display apparatus. As a way to add various functions to the display apparatus while expanding the area of the display region, the display apparatus includes a display panel having an opening in the display region.

### SUMMARY

In a display panel having an opening in a display region, problems such as cracks or film peeling may occur in components arranged around the opening.

Embodiments of the present disclosure include a display panel having, in a display region, an opening around which a component may be arranged. However, this embodiment is merely an examples, and the scope of the present disclosure is not limited thereto.

Additional aspects and features of the present disclosure will be set forth, in part, in the description that follows and, in part, will be apparent from the description or may be learned by practice of the described embodiments.

According to an embodiment of the present disclosure, a display panel includes: a substrate having an opening region, a display region, and a middle region between the opening region and the display region; a plurality of display elements in the display region; an encapsulation layer covering the plurality of display elements and extending from the display region to the middle region; a planarization layer in the middle region and overlapping a portion of the encapsulation layer; a crack sensing portion on the planarization layer and extending around a portion of the opening region; and a cover layer covering a first end of the planarization layer that is on the encapsulation layer and electrically connected to the crack sensing portion.

In an embodiment, the crack sensing portion may include a first connection line and a second connection line, each extending to outside of the middle region, and a crack sensing pattern electrically connecting the first connection line to the second connection line and adjacent to the opening region.

In an embodiment, the first connection line and the crack sensing pattern may be in a first conductive layer, and the second connection line may include a first sub-connection line in the first conductive layer, and a second sub-connection line in a second conductive layer different from the first conductive layer.

In an embodiment, the cover layer may be in the second conductive layer.

In an embodiment, the second sub-connection line may be integrally provided with the cover layer.

In an embodiment, the crack sensing pattern may have a ring shape with one side open.

In an embodiment, the crack sensing pattern may include a first portion having a ring shape with one side open, a second portion connecting one end of the first portion to the first connection line, and a third portion connecting another end of the first portion to the second connection line.

In an embodiment, when viewed in a direction perpendicular to the substrate, the cover layer may have a closed loop shape.

In an embodiment, a groove may be in the middle region and may extend around the opening region, and the planarization layer may cover the groove.

In an embodiment, the groove may have an undercut shape.

According to an embodiment of the present disclosure, a display panel includes: a substrate having an opening region, a display region, and a middle region between the opening region and the display region; a plurality of display elements in the display region; an encapsulation layer covering the plurality of display elements and extending from the display region to the middle region; an input sensing layer on the encapsulation layer; a planarization layer in the middle region and overlapping a portion of the encapsulation layer; a crack sensing portion on the planarization layer and extending around a portion of the opening region; and a cover layer covering a first end of the planarization layer that is on the encapsulation layer and electrically connected to the crack sensing portion.

In an embodiment, the input sensing layer may include a first conductive layer, a second conductive layer, and an insulating layer between the first conductive layer and the second conductive layer, and the cover layer may include a same material as the first conductive layer.

In an embodiment, the crack sensing portion may include a first connection line and a second connection line, each extending to outside of the middle region, and a crack sensing pattern electrically connecting the first connection line to the second connection line and adjacent to the opening region.

In an embodiment, each of the first connection line and the crack sensing pattern may include a same material as the second conductive layer, and the second connection line may include a first sub-connection line including a same material as the second conductive layer and a second sub-connection line including a same material as the first conductive layer.

In an embodiment, the cover layer may be integrally provided with the second sub-connection line.

In an embodiment, when viewed in a direction perpendicular to the substrate, a portion of the first connection line and a portion of the second connection line may overlap the cover layer.

In an embodiment, the crack sensing pattern may have a ring shape with one side open.

In an embodiment, the crack sensing pattern may include a first portion having a ring shape with one side open, a second portion connecting one end of the first portion to the first connection line, and a third portion connecting the other end of the first portion to the second connection line.

In an embodiment, when viewed in a direction perpendicular to the substrate, the cover layer may have a closed loop shape.

In an embodiment, a groove may be in the middle region and may extend around the opening region, and the planarization layer may cover the groove.

Other aspects and features than those described above will become apparent from the following drawings, claims, and detailed description of the present disclosure.

### BRIEF DESCRIPTION OF THE DRAWINGS

The above and other aspects and features of embodiments of the present disclosure will be more apparent from the following description taken in conjunction with the accompanying drawings, in which:

FIG. 1 is a schematic perspective view of an electronic device according to an embodiment;

FIG. 2 is a schematic cross-sectional view of an electronic device according to an embodiment;

FIG. 3 is a schematic plan view of a display panel according to an embodiment;

FIG. 4 is an equivalent circuit diagram of one pixel included in a display panel according to an embodiment;

FIG. 5 is a schematic plan view of a portion of a display panel according to an embodiment;

FIG. 6 is a schematic plan view of a portion of a display panel according to an embodiment;

FIG. 7 is a schematic cross-sectional view of a portion of a display panel according to an embodiment;

FIG. 8 is a schematic plan view of an input sensing layer of a display panel according to an embodiment;

FIG. 9 is a schematic plan view of a portion of an input sensing layer of a display panel according to an embodiment;

FIGS. 10A and 10B are schematic plan views of a first conductive layer and second conductive layer of an input sensing layer according to embodiments;

FIG. 10C is a schematic cross-sectional view of an input sensing layer according to an embodiment;

FIG. 11 is a schematic cross-sectional view of a display panel according to an embodiment;

FIG. 12 is a schematic cross-sectional view of a portion of a display panel according to an embodiment;

FIG. 13 is a schematic cross-sectional view of a portion of a display panel according to an embodiment;

FIGS. 14A and 14B are schematic plan views of a portion of a display panel according to embodiments;

FIG. 15A is a schematic plan view of a portion of a display panel according to an embodiment; and

FIGS. 15B and 15C are schematic cross-sectional views of a portion of a display panel according to embodiments.

### DETAILED DESCRIPTION

Reference will now be made, in detail, to embodiments, examples of which are illustrated in the accompanying drawings. The described embodiments may have different forms and should not be construed as being limited to the descriptions set forth herein. Accordingly, embodiments are merely described below, by referring to the figures, to describe aspects and features of the present description.

Various modifications may be applied to the described embodiments, and embodiments will be illustrated in the drawings and described in the detailed description. The aspects and features of the present embodiments, and methods of achieving the same, will be clearer by referring to the detailed descriptions below in conjunction with the drawings. However, the described embodiments may be implemented in various forms, and the present disclosure is not limited to the embodiments presented below.

Hereinafter, embodiments will be described in detail with reference to the accompanying drawings, and in the description with reference to the drawings. The same or corresponding elements are indicated by the same reference numerals, and redundant descriptions thereof are omitted.

It will be understood that when an element or layer is referred to as being “on,” “connected to,” or “coupled to” another element or layer, it may be directly on, connected, or coupled to the other element or layer or one or more intervening elements or layers may also be present. When an element or layer is referred to as being “directly on,” “directly connected to,” or “directly coupled to” another element or layer, there are no intervening elements or layers present. For example, when a first element is described as being “coupled” or “connected” to a second element, the first element may be directly coupled or connected to the second element or the first element may be indirectly coupled or connected to the second element via one or more intervening elements.

In the figures, dimensions of the various elements, layers, etc. may be exaggerated for clarity of illustration. The same reference numerals designate the same elements. As used herein, the term “and/or” includes any and all combinations of one or more of the associated listed items. Further, the use of “may” when describing embodiments of the present disclosure relates to “one or more embodiments of the present disclosure.” Expressions, such as “at least one of” and “any one of,” when preceding a list of elements, modify the entire list of elements and do not modify the individual elements of the list. For example, the expression “at least one of a, b, or c” indicates only a, only b, only c, both a and b, both a and c, both b and c, all of a, b, and c, or variations thereof. As used herein, the terms “use,” “using,” and “used” may be considered synonymous with the terms “utilize,” “utilizing,” and “utilized,” respectively. As used herein, the terms “substantially,” “about,” and similar terms are used as terms of approximation and not as terms of degree, and are intended to account for the inherent variations in measured or calculated values that would be recognized by those of ordinary skill in the art.

It will be understood that, although the terms first, second, third, etc. may be used herein to describe various elements, components, regions, layers, and/or sections, these elements, components, regions, layers, and/or sections should not be limited by these terms. These terms are used to distinguish one element, component, region, layer, or section from another element, component, region, layer, or section. Thus, a first element, component, region, layer, or section discussed below could be termed a second element, component, region, layer, or section without departing from the teachings of example embodiments.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

The terminology used herein is for the purpose of describing embodiments of the present disclosure and is not intended to be limiting of the present disclosure. As used herein, the singular forms “a” and “an” are intended to include the plural forms as well, unless the context clearly indicates otherwise. It will be further understood that the terms “includes,” “including,” “comprises,” and/or “comprising,” when used in this specification, specify the presence of stated features, integers, steps, operations, elements, and/or components but do not preclude the presence or addition of one or more other features, integers, steps, operations, elements, components, and/or groups thereof.

In the present specification, the x-axis, the y-axis, and the z-axis are not limited to three axes of the rectangular coordinate system and may be interpreted in a broader sense. For example, the x-axis, the y-axis, and the z-axis may be perpendicular to one another or may represent different directions that are not perpendicular to one another.

In the present specification, when a certain embodiment may be implemented differently, a specific process order may be performed differently from the described order. For example, two consecutively described processes may be performed substantially at the same time or performed in an order opposite to the described order.

Sizes of elements in the drawings may be exaggerated for convenience of explanation. In other words, since sizes and thicknesses of elements in the drawings may be arbitrarily illustrated for convenience of explanation, and the following embodiments are not limited thereto.

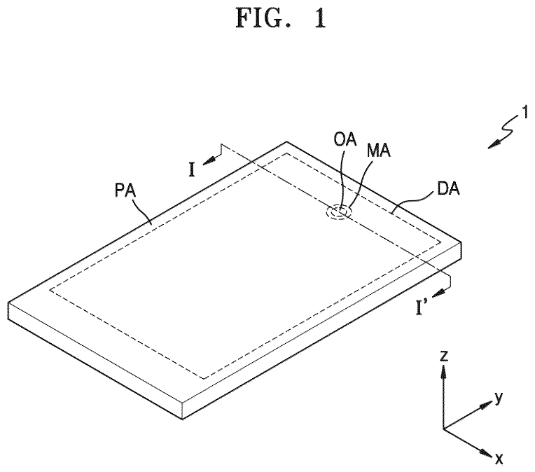

FIG. 1 is a schematic perspective view of an electronic device according to an embodiment.

Referring to FIG. 1, an electronic device 1 is a display apparatus that displays moving images and/or still images and may be used as a display screen for various products, such as televisions, laptops, monitors, billboards, or Internet of Things (IoT) devices, as well as portable electronic devices, such as mobile phones, smartphones, tablet personal computers (tablet PCs), mobile communication terminals, electronic notebooks, e-books, portable multimedia players (PMPs), navigation devices, or ultra-mobile PCs (UMPCs). In addition, the electronic device 1, according to an embodiment, may be used in wearable devices, such as smart watches, watch phones, glass-type displays, and head mounted displays (HMDs). Furthermore, the electronic device 1, according to an embodiment, may be used as a display for an instrument panel for vehicles, a center information display (CID) arranged on the center fascia or dashboard of vehicles, a room mirror display in lieu of a side-view mirror of vehicles, or a display arranged at the rear side of a front seat as an entertainment device for a rear seat of a vehicle. FIG. 1 shows an embodiment in which the electronic device 1 is used as a smartphone as an example.

The electronic device 1 may have a rectangular shape in a plan view. For example, the electronic device 1 may have a rectangular shape having a short side in a first direction (e.g., an x direction) and a long side in a second direction (e.g., a y direction) as shown in FIG. 1. A corner at where the short side in the first direction and the long side in the second direction meet may be rounded with a curvature or may be formed to have a right angle. The planar shape of the electronic device 1 is not limited to a rectangle, and it may have other polygonal, elliptical, or irregular shapes.

The electronic device 1 may have an opening region (e.g., an open region) OA and a display region DA surrounding at least a portion of (e.g., at least partially surrounding in a plan view or at least partially extending around a periphery of) the opening region OA. The electronic device 1 may have a middle region MA arranged between the opening region OA and the display region DA, and an outer region PA outside of the display region DA, for example, surrounding (e.g., extending around a periphery of or surrounding in a plan view) the display region DA. The middle region MA may have a closed loop shape that entirely surrounds the opening region OA in a plan view.

The opening region OA may be arranged inside the display region DA. In an embodiment, the opening region OA may be arranged in the upper center of the display region DA as shown in FIG. 1. In another embodiment, the opening region OA may be arranged in various areas; for example, it may be arranged on an upper left side of the display region DA or arranged on an upper right side of the display region DA. FIG. 1 shows an embodiment in which one opening region OA is arranged, but in some embodiments, a plurality of opening regions OA may be provided.

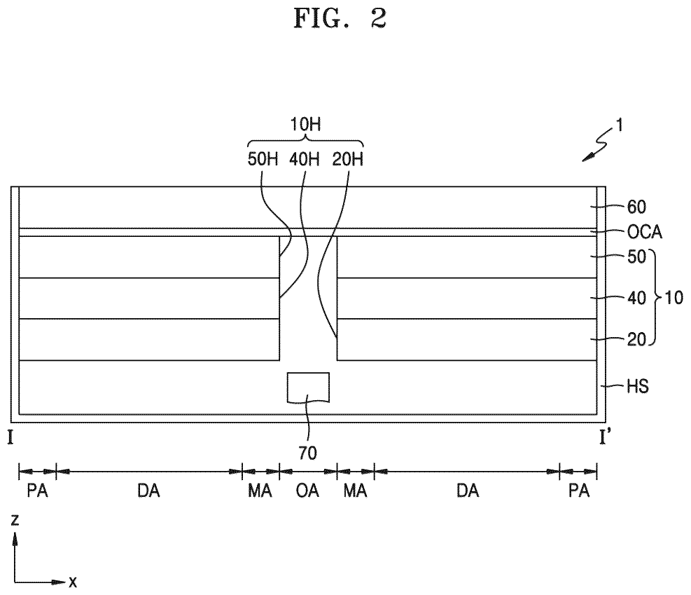

FIG. 2 is a schematic cross-sectional view of an electronic device according to an embodiment. FIG. 2 is a cross-sectional schematic view of the electronic device 1 taken along the line I-I′ in FIG. 1.

Referring to FIG. 2, the electronic device 1 may include a display panel 10, a cover window 60 disposed over the display panel 10, and a component 70 arranged in (or below) the opening region OA in the display panel 10. The display panel 10 and the component 70 may be accommodated in a housing HS.

The display panel 10 may include an image generation layer 20, an input sensing layer 40, and an optical functional layer 50.

The image generation layer 20 may include display elements (e.g., light-emitting elements) that are configured to emit light to display an image. A display element may include a light-emitting diode, for example, an organic light-emitting diode including an organic emission layer. In some embodiments, a light-emitting diode may be an inorganic light-emitting diode including an inorganic material. The inorganic light-emitting diode may include a PN diode including an inorganic semiconductor-based materials. When a voltage is applied to a PN junction diode in a forward direction, holes and electrons are injected, and energy generated due to recombination of the holes and the electrons is converted to light energy so that light of a certain color may be emitted. The inorganic light-emitting diode may have a width in a range of several to hundreds of micrometers or several to hundreds of nanometers. In some embodiments, the image generation layer 20 may include a quantum dot light-emitting diode. For example, an emission layer of the image generation layer 20 may include an organic material, an inorganic material, a quantum dot, an organic material and a quantum dot, or an inorganic material and a quantum dot.

The input sensing layer 40 may obtain coordinate information according to an external input, for example, a touch event. The input sensing layer 40 may include a sensing electrode (e.g., a touch electrode) and trace lines connected to the sensing electrode. The input sensing layer 40 may be disposed on the image generation layer 20. The input sensing layer 40 may sense an external input by using a mutual capacitance method or/and a self-capacitance method.

The input sensing layer 40 may be formed directly on the image generation layer 20 or may be formed separately and then bonded to the image generation layer 20 via an adhesive layer, such as an optically clear adhesive. For example, the input sensing layer 40 may be formed after a process of forming the image generation layer 20 is performed, and in such an embodiment, an adhesive layer may not be arranged (or may be omitted) between the input sensing layer 40 and the image generation layer 20. FIG. 2 shows an embodiment in which the input sensing layer 40 is arranged between the image generation layer 20 and the optical functional layer 50, and in some embodiments, the input sensing layer 40 may be disposed on the optical functional layer 50.

The optical functional layer 50 may include a reflection prevention layer. The reflection prevention layer may reduce reflectance of light (e.g., external light) incident on the display panel 10 from the outside via the cover window 60. The reflection prevention layer may include a retarder and a polarizer. In some embodiments, the reflection prevention layer may include a black matrix and color filters. The color filters may be arranged in consideration of a color of light emitted from each of light-emitting diodes.

To increase transmittance of the opening region OA, the display panel 10 may include a panel hole 10H (e.g., an opening) through some layers of the display panel 10. The panel hole 10H may include a first hole 20H, a second hole 40H, and a third hole 50H respectively penetrating (or extending through) the image generation layer 20, the input sensing layer 40, and the optical functional layer 50. The first hole 20H in the image generation layer 20, the second hole 40H in the input sensing layer 40, and the third hole 50H in the optical functional layer 50 may overlap each other (e.g., may be aligned with each other in a thickness direction of the display panel 10) to form the panel hole 10H in the display panel 10.

The cover window 60 may be disposed over the display panel 10. The cover window 60 may be bonded to the display panel 10 via an adhesive layer, such as an optically clear adhesive OCA arranged between the cover window 60 and the display panel 10. The cover window 60 may cover the first hole 20H in the image generation layer 20, the second hole 40H in the input sensing layer 40, and the third hole 50H in the optical functional layer 50.

The cover window 60 may include glass material or plastic material. The glass material may include ultra-thin glass. The plastic material may include polyethersulfone, polyacrylate, polyether imide, polyethylene naphthalate, polyethylene terephthalate, polyphenylene sulfide, polyarylate, polyimide, polycarbonate, or cellulose acetate propionate.

The opening region OA may be a type of component region (e.g., a sensor region, a camera region, a speaker region, etc.) where the component 70 for providing various functions to the electronic device 1 is arranged.

The component 70 may include an electronic element. For example, the component 70 may be an electronic element that uses (e.g., that senses) light or sound. For example, the electronic element may include a sensor that uses light, such as an infrared sensor, a camera that captures an image by receiving light, a sensor that outputs and senses light or sound to measure distance or recognize fingerprints, etc., a small lamp that outputs light, or a speaker that outputs sound. An electronic element that uses light may use light in various wavelength bands, such as visible light, infrared light, ultraviolet light, etc. The opening region OA corresponds to a region through which light or/and sound output from the component 70 to the outside or traveling from the outside to the electronic element may pass.

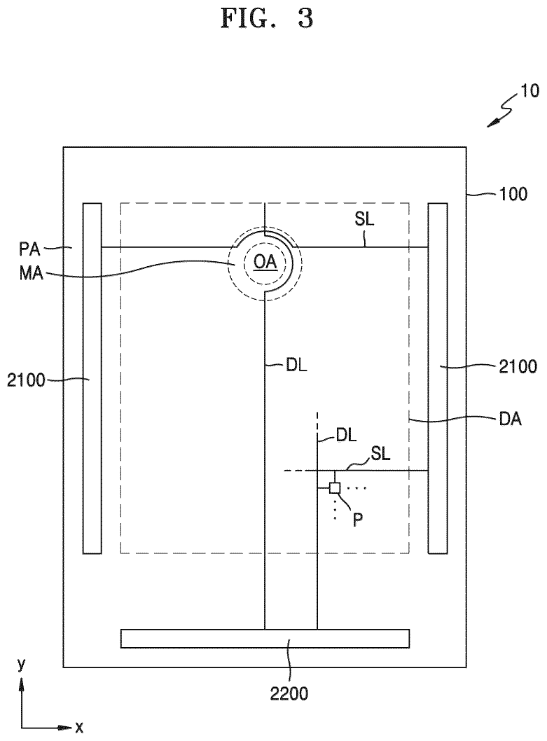

FIG. 3 is a schematic plan view of a display panel according to an embodiment.

Referring to FIG. 3, the display panel 10 may have the opening region OA, the display region DA, the middle region MA, and the outer region PA.

The display panel 10 may include a plurality of pixels P arranged in the display region DA, and the display panel 10 may display an image by using light emitted from each of the pixels P. Each of the pixels P may emit red light, green light, or blue light by using a display element, such as a light-emitting diode. A display element of each sub-pixel may be electrically connected to a scan line SL and a data line DL.

A scan driver 2100 that provides a scan signal to each of the pixels P, a data driver 2200 that provides a data signal to each of the pixels P, and a first main power line and a second main power line that are configured to respectively provide a first power voltage and a second power voltage may be arranged in the outer region PA. The scan driver 2100 may be arranged on both sides with the display region DA therebetween. In such an embodiment, the pixel P arranged on a left side of the opening region OA may be connected to the scan driver 2100 arranged on the left side, and the pixel P arranged on a right side of the opening region OA may be connected to the scan driver 2100 arranged on the right side. In some embodiments, the scan driver 2100 may be arranged on only one side of the outer region PA.

The middle region MA may surround (e.g., may extend around a periphery of) the opening region OA. The middle region MA is where a display element, such as a light-emitting diode that emits light, is not arranged, but trace lines, which are configured to provide signals to the pixels P provided around the opening region OA, may pass through the middle region MA. For example, the data lines DL and/or the scan lines SL cross the display region DA, and portions of the data lines DL and/or the scan lines SL may bypass the middle region MA along an edge of a panel hole formed in the opening region OA. In the embodiment shown in FIG. 3, the data lines DL cross the display region DA in a second direction (e.g., the y direction), and some of the data lines DL bypass the middle region MA to partially surround the opening region OA. The scan lines SL cross the display region DA in a first direction (e.g., the x direction) and may be spaced apart from each other with the opening region OA therebetween. In an embodiment, the scan lines SL may be connected to each other via a connection line that bypasses the middle region MA to partially surround the opening region OA.

FIG. 3 shows that the data driver 2200 is arranged adjacent to one side of a substrate 100, but according to some embodiments, the data driver 2200 may be disposed on a printed circuit board electrically connected to a pad arranged on one side of the display panel 10. The printed circuit board may be flexible, and a portion of the printed circuit board may be bent to be disposed under a rear surface of the substrate 100.

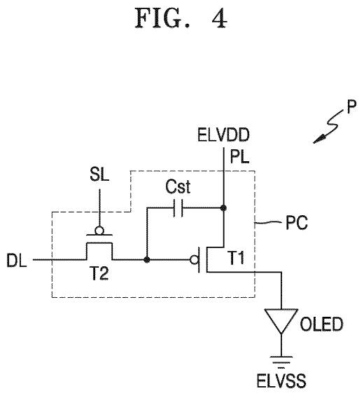

FIG. 4 is a schematic equivalent circuit diagram of one pixel included in a display panel according to an embodiment.

Referring to FIG. 4, one pixel P may include a pixel circuit PC and an organic light-emitting diode OLED as a display element connected to the pixel circuit PC.

The pixel circuit PC may include a first transistor T1, a second transistor T2, and a storage capacitor Cst. Each of the pixels P may emit, for example, red light, green light, blue light, or white light via the organic light-emitting diode OLED.

The first transistor T1, as a driving thin-film transistor, is connected to a driving voltage line PL and the storage capacitor Cst and may be configured to control a driving current flowing from the driving voltage line PL to the organic light-emitting diode OLED according to a voltage value stored in the storage capacitor Cst.

The second transistor T2, as a switching thin-film transistor, is connected to the scan line SL and the data line DL and may be configured to transmit, to the first transistor T1, a data voltage input from the data line DL, according to a switching voltage input from the scan line SL. The storage capacitor Cst is connected to the second transistor T2 and the driving voltage line PL and may store a voltage corresponding to a difference between a voltage received from the second transistor T2 and a first power voltage ELVDD supplied to the driving voltage line PL.

The organic light-emitting diode OLED may emit light having a certain luminance according to the driving current. An opposite electrode (e.g., a cathode) of the organic light-emitting diode OLED may receive a second power voltage ELVSS.

FIG. 4 illustrates an embodiment in which the pixel circuit PC includes two thin-film transistors and one storage capacitor, but the present disclosure is not limited thereto. The number of thin-film transistors and the number of storage capacitors may vary according to the design of the pixel circuit PC. For example, the pixel circuit PC may further include at least four thin-film transistors in addition to the two thin-film transistors.

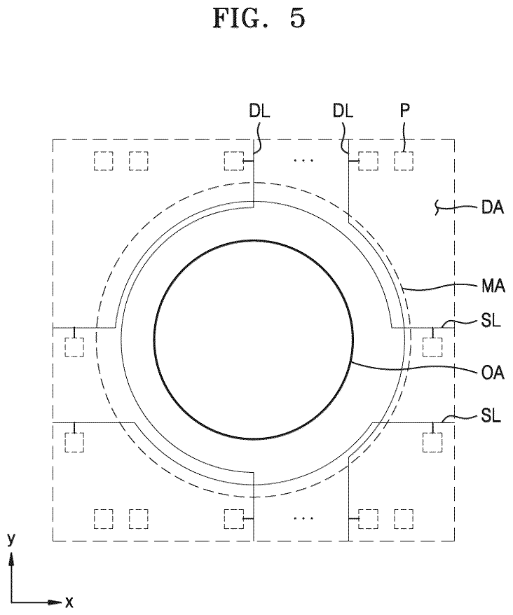

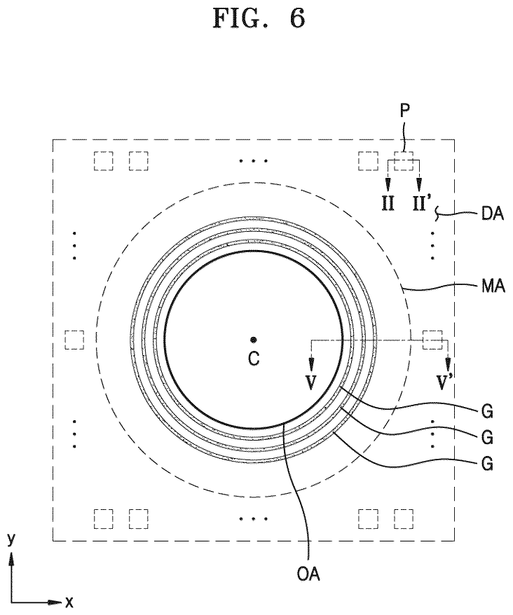

FIGS. 5 and 6 are schematic plan views of a portion of a display panel according to embodiments. FIG. 5 schematically shows trace lines (e.g., the data lines DL and the signal lines SL) adjacent to the opening region OA, and FIG. 6 schematically shows grooves G arranged in the middle region MA.

Referring to FIGS. 5 and 6, the middle region MA may be arranged between the opening region OA and the display region DA. The plurality of pixels P may be arranged in the display region DA. When viewed in a direction perpendicular to the substrate 100, the pixels P adjacent to the opening region OA may be spaced apart from each other with the opening region OA therebetween. For example, the pixels P may be arranged apart from each other above and below the opening region OA or may be arranged apart from each other to the left and right of the opening region OA in a plan view.

From among the trace lines that supply signals to the pixels P, the trace lines (e.g., the data lines DL and the signal lines SL) adjacent to the opening region OA may bypass the opening region OA. From among the data lines DL that pass through the display region DA, some data lines DL adjacent to the opening region OA may extend in a second direction (e.g., the y direction) to provide data signals to the pixels P disposed above and below the opening region OA and may bypass the middle region MA along an edge of the opening region OA. Some scan lines SL from among the scan lines SL that pass through the display region DA may extend in a first direction (e.g., the x direction) to provide scan signals to the pixels P arranged to the left and right of the opening region OA and may bypass the middle region MA along the edge of the opening region OA.

One or more grooves G may be arranged in the middle region MA. In this regard, FIG. 6 shows an embodiment in which three grooves G are arranged spaced apart from each other in the middle region MA. The groove G may have a shape concave in a thickness direction (e.g., the z direction) by removing a portion from one or more layers.

When viewed in a direction perpendicular to the substrate 100, the grooves G may each have a closed loop shape surrounding (e.g., extending around) the opening region OA. For example, the grooves G may have concentric circular shapes that share the opening region OA and a center C but having different diameters.

The grooves G may be arranged closer to the opening region OA than bypass portions, which bypass the opening region OA, of the data lines DL and the scan lines SL. For example, when viewed in a direction perpendicular to the substrate 100, the bypass portions of the data lines DL and the scan lines SL may be arranged closer to the display region DA than the grooves G.

In some embodiments, the display panel may include, instead of the grooves G, one or more separators in the middle region MA. The one or more separators each have a shape protruding from a peripheral region in a thickness direction (e.g., the z direction) and may each have a tip protruding in a direction parallel to the substrate 100. When viewed in a direction perpendicular to the substrate 100, the one or more separators may each have a closed loop shape surrounding the opening region OA.

The grooves G or the one or more separators may cut off or separate an organic material layer, such as an intermediate layer, thereby reducing or blocking a path through which moisture, etc. may penetrate from the panel hole arranged in the opening region OA to a display element.

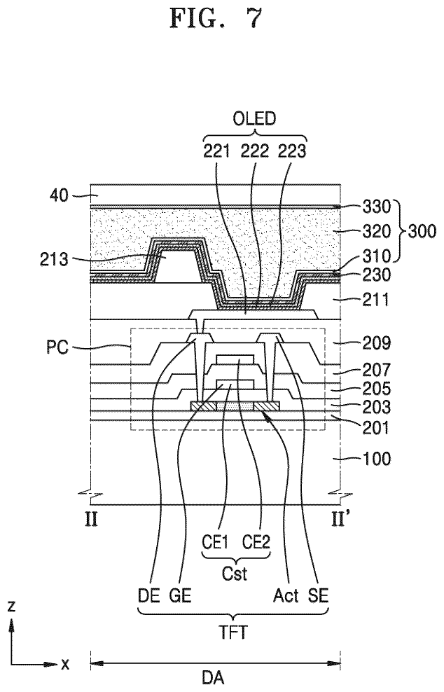

FIG. 7 is a schematic cross-sectional view of a portion of a display panel according to an embodiment. FIG. 7 is a cross-sectional schematic view of the display panel taken along the line II-II′ in FIG. 6.

Referring to FIG. 7, the pixel circuit PC and the organic light-emitting diode OLED as a display element electrically connected to the pixel circuit PC may be arranged in the display region DA. The pixel circuit PC may be disposed over the substrate 100, and the organic light-emitting diode OLED may be disposed over the pixel circuit PC. The pixel circuit PC may include a thin-film transistor TFT and the storage capacitor Cst that are disposed over the substrate 100.

The substrate 100 may include polymer resin or glass material. The substrate 100 may be formed as a multilayer structure. For example, the substrate 100 may include a base layer and a barrier layer.

The base layer may include polymer resin. The polymer resin may include polyethersulfone, polyarylate, polyetherimide, polyethylene naphthalate, polyethylene terephthalate, polyphenylene sulfide, polyimide, polycarbonate, cellulose triacetate, cellulose acetate propionate, etc.

The barrier layer prevents penetration of foreign substances and may be a single layer or a multilayer structure, each including an inorganic insulating material, such as silicon nitride, silicon oxynitride, and silicon oxide.

A buffer layer 201 may be formed on the substrate 100 to prevent penetration of impurities into a semiconductor layer Act of the thin-film transistor TFT. The buffer layer 201 may include an inorganic insulating material, such as silicon nitride, silicon oxynitride, and silicon oxide, and may be a single layer or a multilayer structure, each including the inorganic insulating material.

The pixel circuit PC may be disposed on the buffer layer 201. The pixel circuit PC may include the thin-film transistor TFT and the storage capacitor Cst. The thin-film transistor TFT may include the semiconductor layer Act, a gate electrode GE, a source electrode SE, and a drain electrode DE.

The thin-film transistor TFT shown in FIG. 7 may correspond to a driving transistor described with reference to FIG. 4. In the illustrated embodiment, a top gate transistor is shown, in which the gate electrode GE is disposed over the semiconductor layer Act with a gate insulating layer 203 therebetween, but according to some embodiments, the thin-film transistor TFT may be a bottom gate transistor.

The semiconductor layer Act may include polysilicon. In another embodiment, the semiconductor layer Act may include amorphous silicon, an oxide semiconductor, or an organic semiconductor. The gate electrode GE may include a low-resistance metal material. The gate electrode GE may include a conductive material including molybdenum (Mo), aluminum (Al), copper (Cu), titanium (Ti), etc. and may be formed as a multilayer structure or a single layer, each including the above-described material.

The gate insulating layer 203 between the semiconductor layer Act and the gate electrode GE may include an inorganic insulating material, such as silicon oxide, silicon nitride, silicon oxynitride, aluminum oxide, titanium oxide, tantalum oxide, and hafnium oxide. The gate insulating layer 203 may be a single layer or a multilayer structure, each including the above-described material.

Each of the source electrode SE and the drain electrode DE may include a material having excellent conductivity. Each of the source electrode SE and the drain electrode DE may include a conductive material including molybdenum (Mo), aluminum (Al), copper (Cu), titanium (Ti), etc. and may be formed as a multilayer structure or a single layer, each including the above-mentioned material. In an embodiment, each of the source electrode SE and the drain electrode DE may include a multilayer structure of Ti/Al/Ti. In an embodiment, at least one of the source electrode SE and the drain electrode DE may be omitted, and an impurity region of the semiconductor layer Act may act as a source or drain.

The storage capacitor Cst includes a lower electrode CE1 and an upper electrode CE2 that overlap each other with a first interlayer insulating layer 205 therebetween. The storage capacitor Cst may overlap the thin-film transistor TFT. In this regard, FIG. 7 shows an embodiment in which the gate electrode GE of the thin-film transistor TFT and the lower electrode CE1 of the storage capacitor Cst are integrally formed. In some embodiments, the storage capacitor Cst may not overlap the thin-film transistor TFT. The upper electrode CE2 of the storage capacitor Cst may be covered with a second interlayer insulating layer 207. The upper electrode CE2 of the storage capacitor Cst may include a conductive material including molybdenum (Mo), aluminum (Al), copper (Cu), titanium (Ti), etc. and may be formed as a multilayer structure or a single layer, each including the above-mentioned material.

Each of the first and second interlayer insulating layers 205 and 207 may include an inorganic insulating material, such as silicon oxide, silicon nitride, silicon oxynitride, aluminum oxide, titanium oxide, tantalum oxide, hafnium oxide, etc. Each of the first and second interlayer insulating layers 205 and 207 may be a single layer or a multilayer structure, each including the above-mentioned material.

The pixel circuit PC including the thin-film transistor TFT and the storage capacitor Cst may be covered with a planarization insulating layer 209. The planarization insulating layer 209 may include an organic insulating material, such as a general purpose polymer, such as polymethylmethacrylate (PMMA) or polystyrene (PS), a polymer derivative having a phenolic group, an acrylic polymer, an imide-based polymer, an aryl ether-based polymer, an amide-based polymer, a fluorine-based polymer, a p-xylene-based polymer, a vinyl alcohol-based polymer, and a blend thereof. In an embodiment, the planarization insulating layer 209 may include polyimide. In another embodiment, the planarization insulating layer 209 may include an inorganic insulating material or may include an inorganic insulating material and an organic insulating material. The planarization insulating layer 209 may have a substantially flat upper surface.

The organic light-emitting diode OLED may be disposed on the planarization insulating layer 209. The organic light-emitting diode OLED may include a pixel electrode 221, an opposite electrode 223, and an intermediate layer 222 arranged between the pixel electrode 221 and the opposite electrode 223.

The pixel electrode 221 may be formed on the planarization insulating layer 209. The pixel electrode 221 may include a conductive oxide, such as indium tin oxide (ITO), indium zinc oxide (IZO), zinc oxide (ZnO), indium oxide (In₂O₃), indium gallium oxide (IGO), or an aluminum zinc oxide (AZO). In some embodiments, the pixel electrode 221 may include a reflective film including silver (Ag), magnesium (Mg), aluminum (Al), platinum (Pt), palladium (Pd), gold (Au), nickel (Ni), neodymium (Nd), iridium (Ir), chromium (Cr), or a compound thereof. In some embodiments, the pixel electrode 221 may further include a layer including ITO, IZO, ZnO, or indium oxide (e.g., In₂O₃) above or/and below the reflective film.

A pixel-defining film 211 may be formed on the pixel electrode 221. The pixel-defining film 211 may have an opening that exposes an upper surface of the pixel electrode 221 but may cover an edge of the pixel electrode 221. The pixel-defining film 211 may include an organic insulating material. In another embodiment, the pixel-defining film 211 may include an inorganic insulating material, such as silicon nitride, silicon oxynitride, or silicon oxide. In another embodiment, the pixel-defining film 211 may include an organic insulating material and an inorganic insulating material.

The pixel-defining film 211 may be black. The pixel-defining film 211 may include a light-blocking material. The light-blocking material may include resin or paste including carbon black, carbon nanotubes, or black dye, metal particles, such as nickel (Ni), aluminum (Al), molybdenum (Mo), and an alloy thereof, metal oxide particles (e.g., chromium oxide), or metal nitride particles (e.g., chromium nitride). When the pixel-defining film 211 includes the light-blocking material, reflection of external light by metal structures disposed under the pixel-defining film 211 may be reduced.

The intermediate layer 222 includes an emission layer. The intermediate layer 222 may include a first functional layer disposed below the emission layer and/or a second functional layer disposed over the emission layer. The emission layer may include a polymer or low-molecular weight organic material that emits light of a certain color.

The first functional layer may be a single layer or a multilayer structure. For example, when the first functional layer includes a polymer material, the first functional layer may include poly-(3,4)-ethylene-dihydroxy thiophene or polyaniline as a hole transport layer having a single-layered structure. When the first functional layer includes a low-molecular weight material, the first functional layer may include a hole injection layer and a hole transport layer.

The second functional layer may be a single layer or a multilayer structure. The second functional layer may include an electron transport layer and/or an electron injection layer. In some embodiments, the second functional layer may be omitted.

The emission layer of the intermediate layer 222 may be arranged in each pixel in the display region DA. For example, the emission layer may be patterned to correspond to the pixel electrode 221. The first functional layer and/or the second functional layer of the intermediate layer 222 may be commonly formed across a plurality of organic light-emitting diodes OLED. The first functional layer and/or the second functional layer of the pixel electrode 221 may be arranged not only in the display region DA but also in the middle region MA.

The opposite electrode 223 may be disposed on the intermediate layer 222. The opposite electrode 223 may include a conductive material having a low work function. For example, the opposite electrode 223 may include a (semi-)transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or an alloy thereof. In another embodiment, the opposite electrode 223 may further include a layer including ITO, IZO, ZnO or indium oxide (e.g., In₂O₃) on the (semi-)transparent layer including the above-described material. The opposite electrode 223 may be commonly formed across the plurality of organic light-emitting diodes OLED. The opposite electrode 223 may be arranged not only in the display region DA but also in the middle region MA.

A capping layer 230 may be disposed on the opposite electrode 223. For example, the capping layer 230 may include lithium fluoride (LiF) and may be formed by a thermal deposition method. The capping layer 230 may increase luminescence efficiency of the organic light-emitting diode OLED according to the principle of constructive interference. The capping layer 230 may be an organic capping layer including an organic material, an inorganic capping layer including an inorganic material, or a composite capping layer including an organic material and an inorganic material. In some embodiments, the capping layer 230 may be omitted.

A spacer 213 may be formed on the pixel-defining film 211. The spacer 213 may include an organic insulating material, such as polyimide. In another embodiment, the spacer 213 may include an inorganic insulating material, such as silicon nitride or silicon oxide, or may include an organic insulating material and an inorganic insulating material.

The spacer 213 may include a material different from that of the pixel-defining film 211. In another embodiment, the spacer 213 may include the same material as that of the pixel-defining film 211, and in such an embodiment, the pixel-defining film 211 and the spacer 213 may be formed together in a mask process using a halftone mask, etc. In an embodiment, each of the pixel-defining film 211 and the spacer 213 may include polyimide.

The organic light-emitting diode OLED may be covered with an encapsulation layer 300. The encapsulation layer 300 may include at least one organic encapsulation layer and at least one inorganic encapsulation layer. For example, FIG. 7 shows an embodiment in which the encapsulation layer 300 includes a first inorganic encapsulation layer 310, a second inorganic encapsulation layer 330, and an organic encapsulation layer 320 arranged therebetween. In some embodiments, the number of organic encapsulation layers, the number of inorganic encapsulation layers, and a stacking order thereof may be changed.

Each of the first inorganic encapsulation layer 310 and the second inorganic encapsulation layer 330 may include at least one inorganic material from among aluminum oxide, titanium oxide, tantalum oxide, hafnium oxide, zinc oxide, silicon oxide, silicon nitride, and silicon oxynitride. Each of the first inorganic encapsulation layer 310 and the second inorganic encapsulation layer 330 may be a single layer or a multilayer structure, each including the above-described material.

The organic encapsulation layer 320 may include a polymer-based material. The polymer-based material may include an acrylic resin, an epoxy-based resin, polyimide, and polyethylene. In an embodiment, the organic encapsulation layer 320 may include acrylate.

The input sensing layer 40 may be disposed on the display panel 10. For example, FIG. 7 shows an embodiment in which the input sensing layer 40 is formed directly on the display panel 10 and is in contact with the encapsulation layer 300.

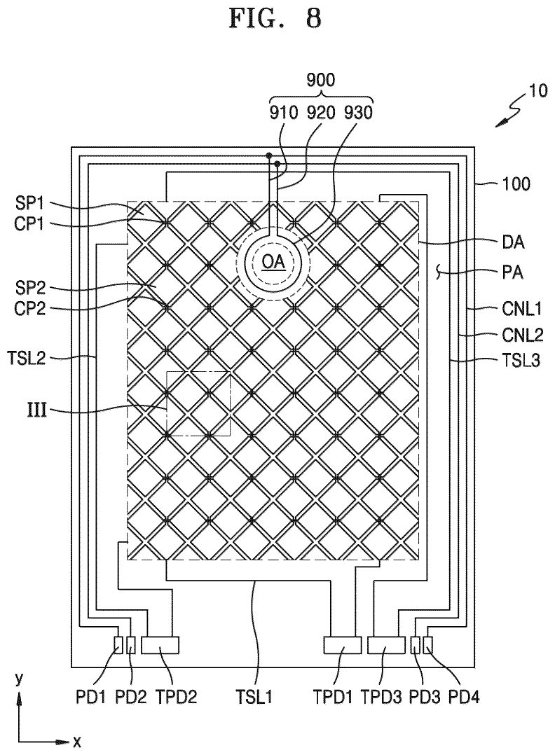

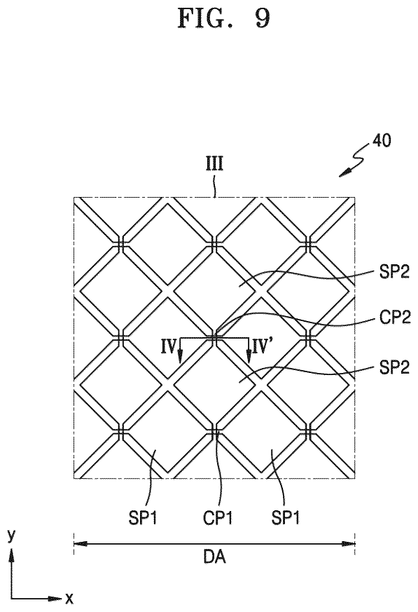

FIG. 8 is a schematic plan view of an input sensing layer of a display panel according to an embodiment, and FIG. 9 is a schematic plan view of a portion of an input sensing layer of a display panel according to an embodiment. FIG. 8 schematically shows a crack sensing portion and crack sensing lines, which are arranged in the same layer as an input sensing layer.

Referring to FIGS. 8 and 9, the display panel 10 may include the input sensing layer 40. The input sensing layer 40 may include first sensing electrodes SP1, second sensing electrodes SP2, first to third input sensing lines TSL1, TSL2, and TSL3, and first to third input sensing pads TPD1, TPD2, and TPD3.

The first sensing electrodes SP1 and the second sensing electrodes SP2 may be arranged in the display region DA. The first sensing electrodes SP1 may be connected to each other in a first direction (e.g., the x direction), and the second sensing electrodes SP2 may be connected to each other in a second direction (e.g., the y direction). The first sensing electrodes SP1 adjacent to each other in a first direction may be electrically connected to each other via a first connection electrode CP1, and the second sensing electrodes SP2 adjacent to each other in a second direction may be electrically connected to each other via a second connection electrode CP2.

When viewed in a direction perpendicular to the substrate 100, the first sensing electrode SP1 and the second sensing electrode SP2 may be arranged apart from each other, and the first connection electrode CP1 and the second connection electrode CP2 may overlap each other. The first connection electrode CP1 and the second connection electrode CP2 may perpendicularly cross each other.

One end of the first sensing electrodes SP1 connected to each other in a first direction (e.g., the x direction) may be connected to the second input sensing pad TPD2 via the second input sensing line TSL2. One end of the second sensing electrodes SP2 connected to each other in a second direction (e.g., the y direction) may be connected to the first input sensing pad TPD1 via the first input sensing line TSL1, and the other end may be connected to the third input sensing pad TPD3 via the third input sensing line TSL3. The first to third input sensing pads TPD1, TPD2, and TPD3 may be electrically connected to pads disposed on a printed circuit board and thus may transmit an electrical signal to an input sensing control unit. In some embodiments, the first input sensing line TSL1 and the first input sensing pad TPD1 are omitted, and thus, only one end of the second sensing electrode SP2 may be connected to the third input sensing pad TPD3.

The second input sensing pad TPD2 may be arranged apart from the first input sensing pad TPD1 and the third input sensing pad TPD3. For example, the second input sensing pad TPD2 may be arranged on a left side of the display panel 10, and the first input sensing pad TPD1 and the third input sensing pad TPD3 may be arranged on a right side of the display panel 10. A data driver or pads that electrically connects the data driver to data lines may be arranged between the second input sensing pad TPD2 and the first input sensing pad TPD1. An embodiment in which the second input sensing line TSL2 and the second input sensing pad TPD2 are arranged on the left side of the display panel 10 and the third input sensing line TSL3, the first input sensing pad TPD1, and the third input sensing pad TPD3 are arranged on the right side of the display panel 10 is illustrated. However, the positions of the first to third input sensing lines TSL1, TSL2, and TSL3 and the first to third input sensing pads TPD1, TPD2, and TPD3 may be changed.

The input sensing layer 40 may sense an external input by using a mutual capacitance method and/or a self-capacitance method. For example, the input sensing layer 40 may be driven by using a mutual capacitance method during a first section (e.g., a first time period) and may be driven by using a self-capacitance method during a second section (e.g., a second time period) to calculate coordinates of an external input. When the input sensing layer 40 is driven by using a mutual capacitance method, driving signals may be applied to the first sensing electrodes SP1 via the second input sensing line TSL2, and sensing signals may be transmitted from the second sensing electrodes SP2 to the input sensing control unit via the first input sensing line TSL1 and the third input sensing line TSL3.

As shown in FIG. 8, the display panel 10 may include a crack sensing portion 900, first and second crack sensing lines CNL1 and CNL2, and first to fourth crack sensing pads PD1, PD2, PD3, and PD4.

The crack sensing portion 900 may include a crack sensing pattern 930 arranged in the middle region MA to be adjacent to the opening region OA, a first connection line 910 configured to connect one end of the crack sensing pattern 930 to the first crack sensing line CNL1, and a second connection line 920 configured to connect the other end of the crack sensing pattern 930 to the second crack sensing line CNL2. The crack sensing pattern 930 may connect the first connection line 910 to the second connection line 920 by bypassing the opening region OA and may have a ring shape with one side (or one portion) open.

FIG. 8 shows an embodiment in which the crack sensing pattern 930 has a ring shape that is open toward an upper side of the display panel 10, the first connection line 910 and the second connection line 920 extend in a second direction (e.g., the y direction), but the present disclosure is not limited thereto. Depending on the position of the opening region OA and the arrangement of surrounding components, the crack sensing pattern 930 may have a ring shape that is open toward a left or right side thereof. In such an embodiment, the first connection line 910 and the second connection line 920 may extend in a first direction (e.g., the x direction).

The first crack sensing line CNL1 may be connected to the first crack sensing pad PD1 and the fourth crack sensing pad PD4, and the second crack sensing line CNL2 may be connected to the second crack sensing pad PD2 and the third crack sensing pad PD3. In an embodiment, the first crack sensing line CNL1 and the second crack sensing line CNL2 may be arranged outside the second input sensing line TSL2 and the third input sensing line TSL3.

Each of the first crack sensing pad PD1 and the third crack sensing pad PD3 may be an input terminal, and each of the second crack sensing pad PD2 and the fourth crack sensing pad PD4 may be an output terminal. For example, an electrical signal input to the first crack sensing pad PD1 may be output to the second crack sensing pad PD2 via the first crack sensing line CNL1, the crack sensing portion 900, and the second crack sensing line CNL2. An electrical signal input to the third crack sensing pad PD3 may be output to the fourth crack sensing pad PD4 via the second crack sensing line CNL2, the crack sensing portion 900, and the first crack sensing line CNL1.

When the crack sensing pattern 930 is damaged, electrical signals output to the second crack sensing pad PD2 and the fourth crack sensing pad PD4 may be smaller than a reference value or may have a value of zero (0). Therefore, whether or not a crack has occurred in a region adjacent to the opening region OA can be determined.

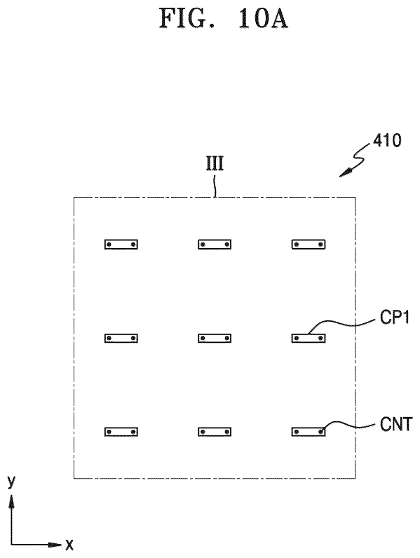

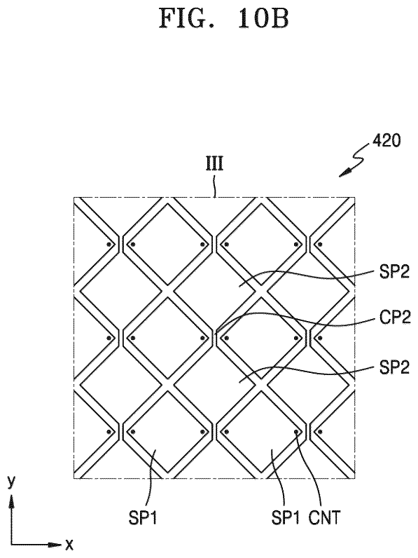

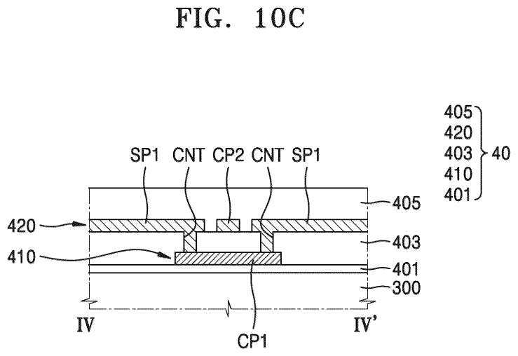

FIGS. 10A and 10B are schematic plan views of a first conductive layer and second conductive layer of an input sensing layer according to embodiments, and FIG. 10C is a schematic cross-sectional view of an input sensing layer according to an embodiment. FIG. 10C is a cross-sectional schematic view of the input sensing layer 40 taken along the line IV-IV′ in FIG. 9.

Referring to FIGS. 10A and 10B, the first sensing electrode SP1 and the second sensing electrode SP2 may be disposed in a same layer. For example, a first conductive layer 410 shown in FIG. 10A may include the first connection electrode CP1, and a second conductive layer 420 shown in FIG. 10B may include the first sensing electrode SP1, the second sensing electrode SP2, and the second connection electrode CP2.

The second sensing electrodes SP2 adjacent to each other in a second direction (e.g., the y direction) may be electrically connected to each other by the second connection electrode CP2 disposed in the same layer as the second sensing electrodes SP2. The second sensing electrodes SP2 connected to each other in a second direction (e.g., the y direction) and the second connection electrodes CP2 connecting the second sensing electrodes SP2 to each other may be integrally provided.

The first sensing electrodes SP1 adjacent to each other in a first direction (e.g., the x direction) may be electrically connected to each other by the first connection electrode CP1 disposed in a different layer from the first sensing electrode SP1. In some embodiments, the first sensing electrode SP1, the second sensing electrode SP2, and the first connection electrode CP1 may be disposed in a same layer, and the second connection electrode CP2 may be disposed in a different layer from the first sensing electrode SP1 and the second sensing electrode SP2.

Referring to FIG. 10C, a middle insulating layer 403 may be arranged between the first conductive layer 410 and the second conductive layer 420. The first sensing electrodes SP1 arranged in the second conductive layer 420 may be connected to the first connection electrode CP1 arranged in the first conductive layer 410 via a contact hole (e.g., a contact opening) CNT in the middle insulating layer 403. The second conductive layer 420 may be covered with an upper insulating layer 405, and a lower insulating layer 401 may be disposed below the first conductive layer 410.

In an embodiment, the first sensing electrode SP1 and the first connection electrode CP1 may be arranged in the first conductive layer 410, and the second sensing electrode SP2 and the second connection electrode CP2 may be arranged in the second conductive layer 420. In such an embodiment, the middle insulating layer 403 may not include a separate contact hole, and the first and second sensing electrodes SP1 and SP2 may be electrically insulated with the middle insulating layer 403 therebetween.

Each of the first conductive layer 410 and the second conductive layer 420 may include a metal layer or a transparent conductive layer. The metal layer may include molybdenum (Mo), silver (Ag), titanium (Ti), copper (Cu), aluminum (Al), and an alloy thereof. The transparent conductive layer may include a transparent conductive oxide, such as indium tin oxide, indium zinc oxide, zinc oxide, or indium tin zinc oxide. In addition, the transparent conductive layer may include a conductive polymer, such as PEDOT, a metal nanowire, a carbon nanotube, graphene, etc.

Each of the lower insulating layer 401, the middle insulating layer 403, and the upper insulating layer 405 may be an organic insulating layer or an inorganic insulating layer. In some embodiments, the lower insulating layer 401 may be omitted, and the first conductive layer 410 may be disposed directly on the encapsulation layer 300.

In an embodiment, each of the first sensing electrode SP1, the second sensing electrode SP2, the first connection electrode CP1, and the second connection electrode CP2 may have a mesh structure including a plurality of holes (e.g., a plurality of openings). The plurality of holes may be arranged to overlap an emission region of a display element.

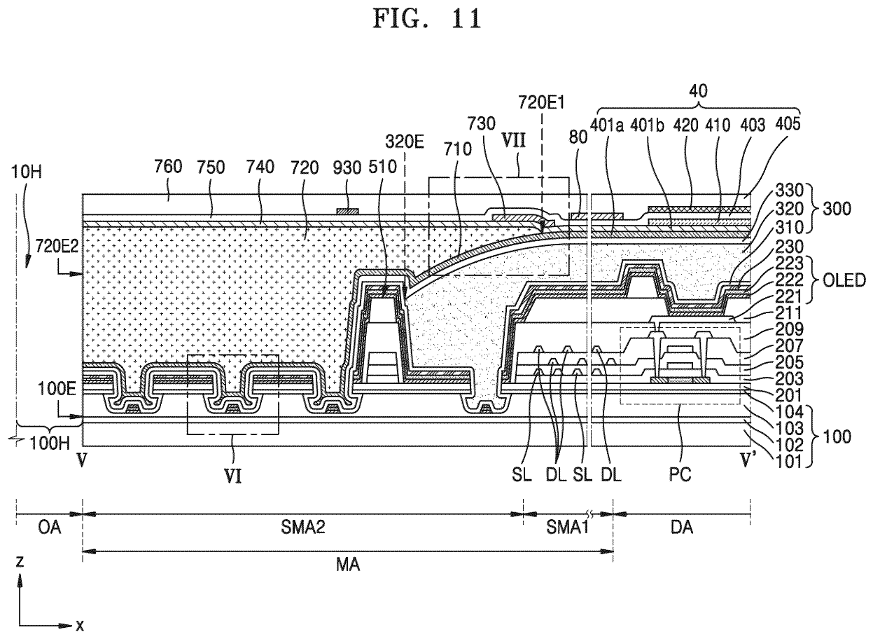

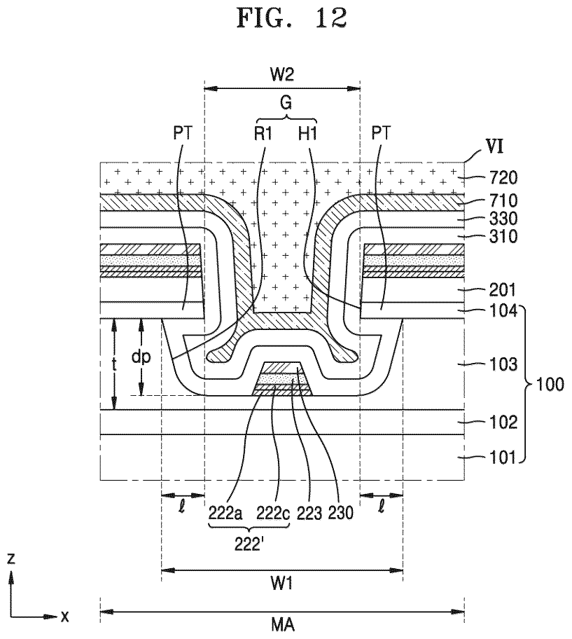

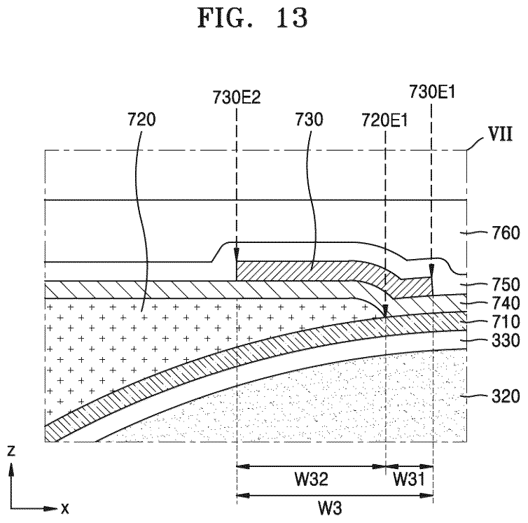

FIG. 11 is a schematic cross-sectional view of a display panel according to an embodiment, and FIGS. 12 and 13 are schematic cross-sectional views of portions of a display panel according to embodiments. FIG. 11 is a cross-sectional schematic view of the display panel taken along the line V-V′ in FIG. 6, FIG. 12 is a cross-sectional schematic view of the portion VI of the display panel shown in FIG. 11, and FIG. 13 is a cross-sectional schematic view of the portion VII of the display panel shown in FIG. 11.

Referring to FIG. 11, the display panel 10 may have the opening region OA in which the panel hole 10H is arranged, the display region DA, and the middle region MA arranged between the opening region OA and the display region DA. The pixel circuit PC over the substrate 100 and the organic light-emitting diode OLED electrically connected to the pixel circuit PC may be arranged in the display region DA.

The substrate 100 may be a multilayer structure. For example, the substrate 100 may include a first base layer 101, a first barrier layer 102, a second base layer 103, and a second barrier layer 104, which are sequentially stacked on each other. Each of the first base layer 101 and the second base layer 103 may include a polymer resin. Each of the first barrier layer 102 and the second barrier layer 104 prevents penetration of foreign substances and may be a single layer or a multilayer structure, each including an inorganic insulating material, such as silicon nitride, silicon oxynitride, and silicon oxide.

The buffer layer 201 may be disposed on the substrate 100, and the pixel circuit PC may be disposed on the buffer layer 201. The pixel circuit PC may include thin-film transistors and a storage capacitor. The planarization insulating layer 209 may be disposed on the pixel circuit PC, and the organic light-emitting diode OLED may be disposed on the planarization insulating layer 209. The organic light-emitting diode OLED may include the pixel electrode 221, the opposite electrode 223, and the intermediate layer 222 arranged between the pixel electrode 221 and the opposite electrode 223. The organic light-emitting diode OLED may be covered by the encapsulation layer 300.

The middle region MA may include a first sub-middle region SMA1 relatively adjacent to the display region DA and a second sub-middle region SMA2 relatively adjacent to the opening region OA.

The first sub-middle region SMA1 may be a region through which trace lines (e.g., the data lines DL and the signal lines SL) pass. The data lines DL and the scan lines SL shown in FIG. 11 may each correspond to a bypass portion that bypasses the opening region OA. For example, the first sub-middle region SMA1 may be a line region or bypass region through which the data lines DL and the scan lines SL pass.

The data lines DL may be alternately arranged with an insulating layer therebetween. When the data lines DL adjacent to each other are disposed above and below an insulating layer (e.g., the second interlayer insulating layer 207), gaps (e.g., pitches) between the adjacent data lines DL may be reduced, and the width of the middle region MA may be reduced.

FIG. 11 shows an embodiment in which the scan lines SL are arranged between the gate insulating layer 203 and the first interlayer insulating layer 205, and the data lines DL are arranged between the first interlayer insulating layer 205 and the second interlayer insulating layer 207 and between the second interlayer insulating layer 207 and the planarization insulating layer 209, but the disclosure is not limited thereto. In some embodiments, the data lines DL may be arranged between the second interlayer insulating layer 207 and the planarization insulating layer 209, and the scan lines SL may be arranged between the first interlayer insulating layer 205 and the second interlayer insulating layer 207.

A shield layer 80 may be disposed on the data lines DL or/and the scan lines SL located in the first sub-middle region SMA1. The shield layer 80 may be arranged to overlap the data lines DL or/and the scan lines SL, thereby preventing the data lines DL or/and the scan lines SL from being visible to a user. In an embodiment, the shield layer 80 may include metal.

One or more grooves or separators may be arranged in the second sub-middle region SMA2. FIG. 11 shows an embodiment of a display panel that has four grooves in the second sub-middle region SMA2, but the number of grooves may vary.

Each of the grooves G may be formed in a multilayer film including a first layer and a second layer, which include different materials from each other. For example, FIG. 12 shows an embodiment in which the groove G is formed in a sub-layer provided on the substrate 100.

Referring to FIG. 12, the groove G may be formed by removing a portion of the second barrier layer 104 and a portion of the second base layer 103. A hole (e.g., an opening) H1 defined in the second barrier layer 104 and a recess R1 defined in the second base layer 103 may be spatially connected to form the groove G. The second base layer 103 may correspond to the first layer of the multilayer film, and the second barrier layer 104 may correspond to the second layer of the multilayer film.

In a process of forming the groove G, a portion of the buffer layer 201 on the second barrier layer 104 may be removed together with the second barrier layer 104 to define the hole H1. Although the buffer layer 201 and the second barrier layer 104 are described as separate components, the buffer layer 201 on the substrate 100 may be a sub-layer of the second barrier layer 104 having a multilayer structure.

A portion of the groove G, which penetrates (or extends through) the second barrier layer 104, for example, the width of the hole H1, may be smaller than a portion of the groove G, which penetrates the second base layer 103, for example, the width of the recess R1. A width (or diameter) W2 of the hole H1 may be smaller than a width (or diameter) W1 of the recess R1, and the groove G may have an undercut shape.

Therefore, a side surface of the second barrier layer 104 defining the hole H1 may protrude further toward a center of the groove G than a side surface of the second base layer 103 defining the recess R1. Portions of the second barrier layer 104 protruding toward the center of the groove G may form a pair of eaves (e.g., a pair of tips) PT. The length (f) of each of the pair of tips PT may be less than about 2.0 μm. In an embodiment, the length (f) may be in a range of about 1.0 μm to about 1.8 μm.

The groove G may be formed before a process of forming the intermediate layer 222. The emission layer of the intermediate layer 222 may be arranged in each pixel in correspondence with the pixel electrode 221, and a portion 222′ of the intermediate layer 222 may extend from the display region DA to the middle region MA. For example, a first functional layer 222a and/or a second functional layer 222c may be arranged in the middle region MA.

The portion 222′ of the intermediate layer 222, which extends to the middle region MA, may be separated or cut off by the groove G. Similarly, the opposite electrode 223 and the capping layer 230 may also be separated or cut off by the groove G.

FIGS. 11 and 12 show embodiments in which a bottom surface of the groove G is disposed on a virtual plane between a lower surface and upper surface of the second base layer 103, but in some embodiments, the bottom surface of the groove G may be coplanar with the lower surface of the second base layer 103. For example, in an etching process to form the groove G, the depth (dp) of the recess R1 may be substantially the same as the thickness (t) of the second base layer 103, and in such an embodiment, the bottom surface of the groove G may be coplanar with the lower surface of the second base layer 103 (e.g., may be disposed on an upper surface of the first barrier layer 102). When the depth (dp) of the recess R1 is the same as the thickness (t) of the second base layer 103, the recess R1 may be understood as a hole penetrating (or extending through) the second base layer 103.

The encapsulation layer 300 that covers display elements in the display region DA may extend to cover the middle region MA, as shown in FIG. 11. For example, the first inorganic encapsulation layer 310 and the second inorganic encapsulation layer 330 may extend from the display region DA to the middle region MA. The first inorganic encapsulation layer 310 and the second inorganic encapsulation layer 330 may be formed by chemical vapor deposition (CVD), etc., and may have relatively better step coverage than the intermediate layer 222 or the opposite electrode 223. Therefore, each of the first inorganic encapsulation layer 310 and the second inorganic encapsulation layer 330 may be formed continuously without being cut off by the groove G (e.g., each of the first inorganic encapsulation layer 310 and the second inorganic encapsulation layer 330 may continuously extend over the groove G). The first inorganic encapsulation layer 310 may cover an inner surface of the groove G. The first inorganic encapsulation layer 310 may be in direct contact with a lower surface of the tip PT protruding from the recess R1 to form an inorganic contact portion where inorganic materials come into contact with each other. The inorganic contact portion may block or reduce a path through which moisture, etc. penetrates from a border of the panel hole 10H.

The organic encapsulation layer 320 may cover the display region DA as shown in FIG. 11, but an end 320E of the organic encapsulation layer 320 may be arranged on one side of a first partition wall 510 arranged in the middle region MA. The organic encapsulation layer 320 may be formed by applying and curing a monomer, and the flow of the monomer may be controlled by (e.g., may be stopped by) the first partition wall 510. The organic encapsulation layer 320, for example, the end 320E of the organic encapsulation layer 320, is arranged spaced apart from the opening region OA, thereby preventing moisture, etc., which has been penetrated from the border of the panel hole 10H, from traveling to the organic light-emitting diode OLED of the display region DA through the organic encapsulation layer 320.

The first partition wall 510 may include a plurality of layers. For example, FIG. 11 shows an embodiment in which the first partition wall 510 has a structure including a stack of layers including the same materials as those of the gate insulating layer 203, the first interlayer insulating layer 205, and the second interlayer insulating layer 207, and layers including the same materials as those of the planarization insulating layer 209 and the pixel-defining film 211. In some embodiments, some of layers of the first partition wall 510 may be omitted or additional layers may be added.

A planarization layer 720 may be arranged in the middle region MA. The planarization layer 720 may include an organic insulating material. The planarization layer 720 may include a polymer-based material. For example, the planarization layer 720 may include a silicon-based resin, an acrylic resin, an epoxy-based resin, polyimide, and polyethylene. The polymer-based material may be transparent.

The planarization layer 720 may cover at least one groove G arranged in the middle region MA. The planarization layer 720 may cover at least a region that is not covered with the organic encapsulation layer 320 in the middle region MA and, thus, may improve the flatness of the display panel 10 around the opening region OA. Therefore, a problem, such as separation or detachment of the input sensing layer 40 (see, e.g., FIG. 2) and/or the optical functional layer 50 (see, e.g., FIG. 2), may be prevented or mitigated. A portion of the planarization layer 720 may overlap the organic encapsulation layer 320. One end of the planarization layer 720, for example, a first end 720E1 adjacent to the display region DA, may be disposed over the organic encapsulation layer 320. For example, the first end 720E1 of the planarization layer 720 may be arranged closer to the display region DA than the end 320E of the organic encapsulation layer 320 is.

A first insulating layer 710 may be disposed directly below the planarization layer 720. The planarization layer 720 may be in direct contact with an upper surface of the first insulating layer 710. The first insulating layer 710 may include an inorganic insulating material, such as silicon oxide, silicon nitride, or silicon oxynitride. The first insulating layer 710 may be in direct contact with the encapsulation layer 300. For example, the first insulating layer 710 may be in direct contact with an upper surface of the second inorganic encapsulation layer 330. The first insulating layer 710 may include the same material as that of the second inorganic encapsulation layer 330 or may include a different material from that of the second inorganic encapsulation layer 330. When the first insulating layer 710 includes the same material as that of the second inorganic encapsulation layer 330, for example, silicon nitride, a specific composition ratio (e.g., the content ratio of silicon and nitrogen, etc.) may be different, and an interface may be formed between the first insulating layer 710 and the second inorganic encapsulation layer 330.

A second insulating layer 740 may be disposed on the planarization layer 720, for example, directly on the planarization layer 720. The second insulating layer 740 may include an inorganic insulating material, such as silicon oxide, silicon nitride, or silicon oxynitride. The first insulating layer 710 and the second insulating layer 740 may include the same or different materials. The thickness of the second insulating layer 740 may be greater than the thickness of the first insulating layer 710. In another embodiment, the thickness of the second insulating layer 740 may be smaller than or equal to the thickness of the first insulating layer 710.

In embodiments, an insulating layer, for example, the first insulating layer 710 and the second insulating layer 740, may be arranged above and below the planarization layer 720, thereby preventing or reducing the penetration of moisture and/or the lifting of films during and after a process of forming the planarization layer 720.

The planarization layer 720 may form a step difference with a layer therebelow. Referring to FIGS. 11 and 13, the first end 720E1 of the planarization layer 720 may form a step difference with a layer therebelow, for example, the upper surface of the first insulating layer 710. In an operation of manufacturing the display panel 10 or/and an operation of using the display panel 10 after the manufacturing of the display panel 10, to prevent a problem in which the planarization layer 720 is separated or peeled off from the layer therebelow due to the step difference, the first end 720E1 of the planarization layer 720 may be covered with the second insulating layer 740 and/or a cover layer 730. The cover layer 730 may include a different material than that of each of the first insulating layer 710 and the second insulating layer 740. For example, the cover layer 730 may include the same material as that of the first conductive layer 410 and/or the second conductive layer 420 of the input sensing layer 40 arranged in the display region DA. In an embodiment, the cover layer 730 may include a metal layer.

A third width W3 of the cover layer 730 may be in a range of about tens of μm to about hundreds of μm. For example, the third width W3 of the cover layer 730 may be in a range of about 50 μm to about 500 μm, in a range of about 50 μm to about 400 μm, in a range of about 50 μm to about 300 μm, in a range of about 50 μm to about 200 μm, in a range of about 50 μm to about 100 μm, or in a range of about 60 μm to about 100 μm.

The cover layer 730 may be disposed over the planarization layer 720. For example, the cover layer 730 may be disposed directly on the second insulating layer 740. A first end 730E1 of the cover layer 730 may be arranged closer to the display region DA than the first end 720E1 of the planarization layer 720 is. Therefore, when viewed in a direction perpendicular to the substrate 100, a first portion of the cover layer 730 including the first end 730E1 may not overlap the planarization layer 720. A second end 730E2 of the cover layer 730 may be arranged closer to the opening region OA than the first end 720E1 of the planarization layer 720 is. Therefore, when viewed in a direction perpendicular to the substrate 100, a second portion of the cover layer 730 including the second end 730E2 may overlap the planarization layer 720. A width W31 of the first portion of the cover layer 730 may be smaller than or equal to a width W32 of the second portion of the cover layer 730.

A third insulating layer 750 and a fourth insulating layer 760 may be disposed on the cover layer 730. The third insulating layer 750 may include an inorganic insulating material, such as silicon oxide, silicon nitride, and/or silicon oxynitride. In another embodiment, the third insulating layer 750 may include an organic insulating material. The fourth insulating layer 760 may include an inorganic insulating material or may include an organic insulating material. The fourth insulating layer 760 including an organic insulating material may have a relatively flat upper surface. The organic insulating material may include a photoresist (negative or positive) or a polymer-based organic material.

At least one of the first insulating layer 710, the second insulating layer 740, the third insulating layer 750, and the fourth insulating layer 760 may include the same material as that of an insulating layer included in the input sensing layer 40. In an embodiment, each of the first insulating layer 710, the second insulating layer 740, the third insulating layer 750, and the fourth insulating layer 760 may be formed by the same process as at least one insulating layer of the input sensing layer 40. For example, as shown in FIG. 11, the first insulating layer 710 may include the same material as that of a first sub-insulating layer 401a, which is a portion of the lower insulating layer 401 of the input sensing layer 40, and may be integrally formed with the first sub-insulating layer 401a. The second insulating layer 740 may include the same material as that of a second sub-insulating layer 401b, which is a portion of the lower insulating layer 401, and may be integrally formed with the second sub-insulating layer 401b. The third insulating layer 750 may include the same material as that of the middle insulating layer 403 of the input sensing layer 40 and may be integrally formed with the middle insulating layer 403. The fourth insulating layer 760 may include the same material as that of the upper insulating layer 405 of the input sensing layer 40 and may be integrally formed with the upper insulating layer 405. In an embodiment, each of the first insulating layer 710, the second insulating layer 740, and the third insulating layer 750 may include an inorganic insulating material, and the fourth insulating layer 760 may include an organic insulating material. Herein, when A and B are described as including a same material, it may indicate that A and B are deposited during a same process and separated or spaced apart by patterning, etc., and have a same stacked structure, a same film quality, etc.

In an embodiment, the cover layer 730 may be disposed in the same layer as the first conductive layer 410 or the second conductive layer 420 of the input sensing layer 40 arranged in the display region DA. FIG. 11 shows an embodiment in which the cover layer 730 is disposed in the same layer (e.g., a layer between the second insulating layer 740 and the third insulating layer 750) as the first conductive layer 410. In some embodiments, the cover layer 730 may include the same material as that of the first conductive layer 410.

The crack sensing pattern 930 may be disposed over (or in) the middle region MA. The crack sensing pattern 930 may be disposed over the planarization layer 720. The crack sensing pattern 930 may be disposed in the same layer as the first conductive layer 410 or the second conductive layer 420 of the input sensing layer 40 arranged in the display region DA. For example, FIG. 11 shows an embodiment in which the crack sensing pattern 930 is disposed in the same layer (e.g., a layer between the third insulating layer 750 and the fourth insulating layer 760) as the second conductive layer 420. In some embodiments, the crack sensing pattern 930 may include the same material as that of the second conductive layer 420.

The panel hole 10H in the display panel may be formed by forming the above-mentioned components and layers on the substrate 100 and then performing a cutting or scribing process. FIG. 11 may be understood as showing a cross-section of a display panel having formed therein the panel hole 10H by performing a cutting or scribing process. At a border of the opening region OA, ends of layers disposed over the substrate 100 may be disposed on the same vertical line as an end 100E of the substrate 100, which defines the panel hole 10H. For example, a second end 720E2 arranged on the opposite side of the first end 720E1 of the planarization layer 720 may be disposed on the same vertical line as the end 100E of the substrate 100.

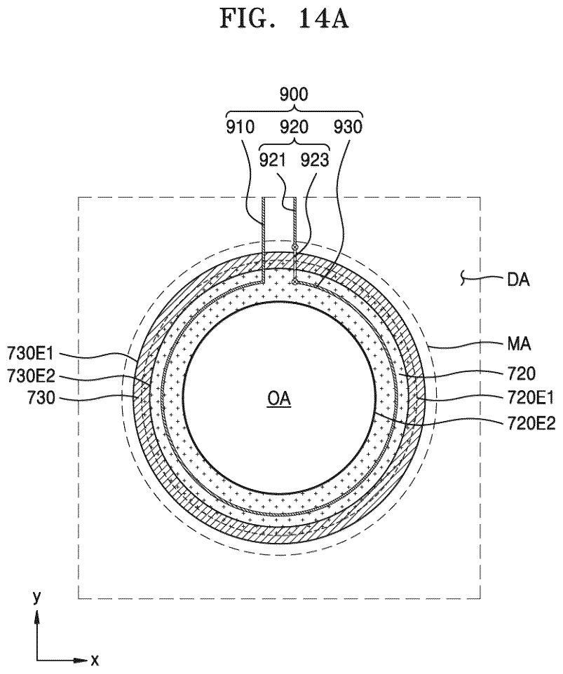

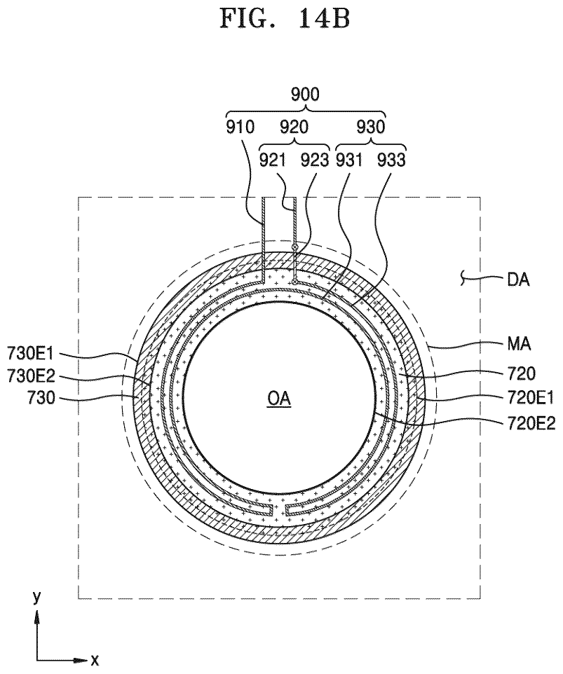

FIGS. 14A and 14B are schematic plan views of a portion of a display panel according to embodiments. For convenience of explanation, FIGS. 14A and 14B show excerpts of the planarization layer 720, the cover layer 730, and the crack sensing portion 900.

Referring to FIGS. 14A and 14B, the planarization layer 720 is arranged in the middle region MA and may have a closed loop shape surrounding (e.g., extending around a periphery of) the opening region OA. The planarization layer 720 is arranged in the middle region MA, but when viewed in a direction perpendicular to the substrate 100, the second end 720E2 of the planarization layer 720 may be substantially the same as (e.g., may be aligned with or may form) the border of the opening region OA.

The cover layer 730 may cover the first end 720E1 of the planarization layer 720. For example, when viewed in a direction perpendicular to the substrate 100, the first end 730E1 of the cover layer 730 may be arranged closer to the display region DA than the first end 720E1 of the planarization layer 720 is, and the second end 730E2 of the cover layer 730 may be arranged closer to the opening region OA than the first end 720E1 of the planarization layer 720 is. Therefore, when viewed in a direction perpendicular to the substrate 100, the first portion of the cover layer 730 including the first end 730E1 may not overlap the planarization layer 720, and the second portion of the cover layer 730 including the second end 730E2 may overlap the planarization layer 720.

The cover layer 730 may have a closed loop shape to completely cover the first end 720E1 of the planarization layer 720. For example, the cover layer 730 may have a ring shape that completely surrounds the opening region OA. In some embodiments, the cover layer 730 may have a ring shape having an open region to partially surround the opening region OA.

The crack sensing portion 900 may include the first connection line 910 and the second connection line 920, which extend to the outside of the middle region MA, and the crack sensing pattern 930 arranged adjacent to the opening region OA. One end of the crack sensing pattern 930 may be connected to the first connection line 910, and the other end of the crack sensing pattern 930 may be connected to the second connection line 920. For example, the first connection line 910 and the second connection line 920 may be connected to each other via the crack sensing pattern 930.

As shown in FIG. 14A, the crack sensing pattern 930 may have a ring shape with one side open, which partially surrounds the opening region OA. In some embodiments, as shown in FIG. 14B, the crack sensing pattern 930 may include a first portion having a ring shape with one side open, which surrounds a portion of the opening region OA, a second portion connecting one end of the first portion to the first connection line 910, and a third portion connecting the other end of the first portion to the second connection line 920. For example, the crack sensing pattern 930 may have a shape in which a first ring portion 931 with one side open and a second ring portion 933 having a greater diameter than the diameter of the first ring portion 931 and having one side open surround the opening region OA in two layers.

The crack sensing pattern 930 may be arranged closer to the opening region OA than the second end 730E2 of the cover layer 730 is. For example, when viewed in a direction perpendicular to the substrate 100, the crack sensing pattern 930 may be arranged between the opening region OA and the cover layer 730.

The first connection line 910 and the second connection line 920 may be arranged to cross the cover layer 730. In this regard, FIGS. 14A and 14B show that the first connection line 910 and the second connection line 920 extend in a second direction (e.g., the y direction), but depending on the position of the opening region OA, the first connection line 910 and the second connection line 920 may extend in various directions and may cross the cover layer 730. When viewed in a direction perpendicular to the substrate 100, a portion of the first connection line 910 and a portion of the second connection line 920 may overlap the cover layer 730.

In an embodiment, the first connection line 910 and the crack sensing pattern 930 may be disposed in a different layer from the cover layer 730. The second connection line 920 may include a first sub-connection line 921 disposed in the same layer as the first connection line 910 and the crack sensing pattern 930, and a second sub-connection line 923 disposed in the same layer as the cover layer 730. In some embodiments, the second sub-connection line 923 may be integrally provided (e.g., integrally formed) with the cover layer 730.

In an embodiment, the first connection line 910 and the crack sensing pattern 930 may be disposed in the same layer as the cover layer 730, and the second connection line 920 may include the first sub-connection line 921 disposed in the same layer as the cover layer 730, and the second sub-connection line 923 disposed in a different layer from the cover layer 730. In some embodiments, the first connection line 910 and the cover layer 730 may be integrally provided (e.g., integrally formed).

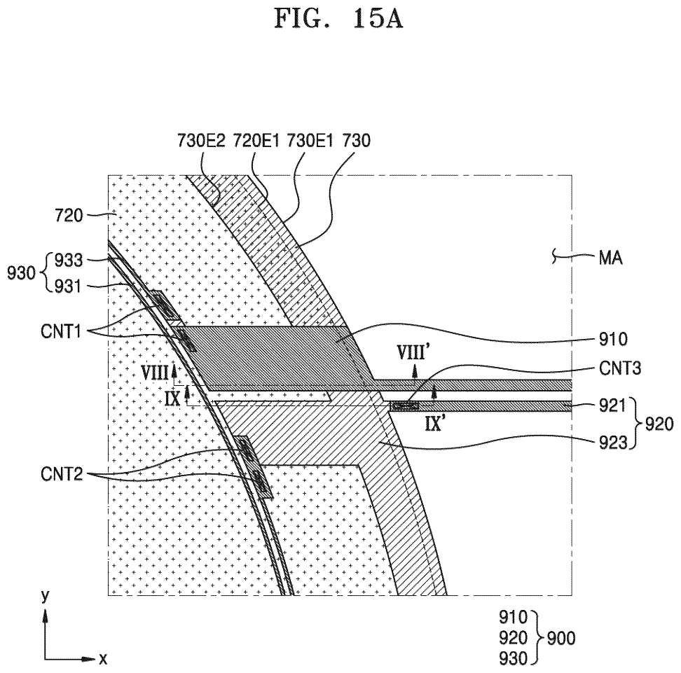

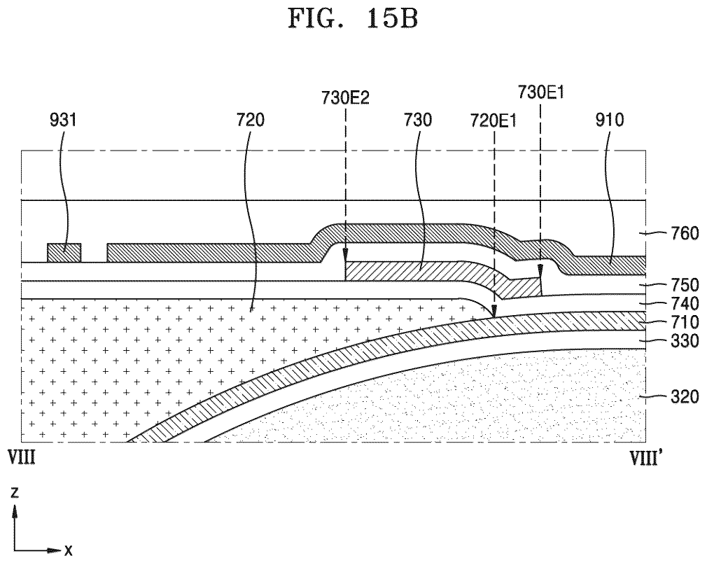

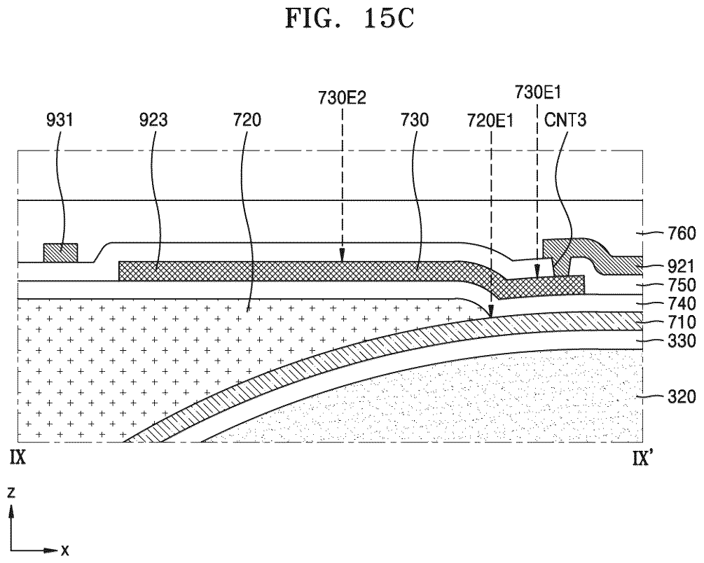

FIG. 15A is a schematic plan view of a portion of a display panel according to an embodiment, and FIGS. 15B and 15C are schematic cross-sectional views of a portion of a display panel according to embodiments. FIG. 15B is a cross-sectional schematic taken along the line VIII-VIII′ in FIG. 15A, and FIG. 15C is a cross-sectional schematic view taken along the line IX-IX′ in FIG. 15A.

Referring to FIGS. 15A to 15C, the cover layer 730 may cover the first end 720E1 adjacent to the display region DA of the planarization layer 720. For example, when viewed in a direction perpendicular to the substrate 100, the first end 730E1 of the cover layer 730 may be arranged closer to the display region DA than the first end 720E1 of the planarization layer 720 is, and the second end 730E2 of the cover layer 730 may be arranged closer to the opening region OA (see, e.g., FIG. 14B) than the first end 720E1 of the planarization layer 720 is.

The crack sensing portion 900 may include the first connection line 910 and the second connection line 920, which extend to the outside of the middle region MA, and the crack sensing pattern 930 arranged adjacent to the opening region OA. The crack sensing pattern 930 may be arranged closer to the opening region OA than the second end 730E2 of the cover layer 730 is. As described above with reference to FIG. 14B, the crack sensing pattern 930 may have a shape in which the first ring portion 931 with one side open and the second ring portion 933 having a greater diameter than the diameter of the first ring portion 931 and having both sides open surround the opening region OA in two layers.

The first connection line 910 and the second connection line 920 may be arranged to cross the cover layer 730. For example, FIGS. 15A to 15C show an embodiment in which the first connection line 910 and the second connection line 920 extend in a first direction (e.g., the x direction). When viewed in a direction perpendicular to the substrate 100, a portion of the first connection line 910 and a portion of the second connection line 920 may overlap the cover layer 730.

In an embodiment, the first connection line 910 may be disposed in the same layer as the crack sensing pattern 930. In some embodiments, the second connection line 920 may include the first sub-connection line 921 disposed in the same layer as the first connection line 910 and the second sub-connection line 923 disposed in a different layer from the first connection line 910 and the crack sensing pattern 930. The second sub-connection line 923 may be disposed in the same layer as the cover layer 730. The second sub-connection line 923 may be electrically connected to the cover layer 730.

For example, FIGS. 15B and 15C show an embodiment in which the first connection line 910, the first ring portion 931 of the crack sensing pattern 930, and the first sub-connection line 921 are arranged between the third insulating layer 750 and the fourth insulating layer 760, and the second sub-connection line 923 and the cover layer 730 are arranged between the second insulating layer 740 and the third insulating layer 750.

As shown in FIG. 15C, the second sub-connection line 923 may be integrally provided (e.g., integrally formed) with the cover layer 730. In another embodiment, as shown in FIG. 15B, one or more insulating layers (e.g., the third insulating layer 750) are arranged between the first connection line 910 and the cover layer 730, and thus, the first connection line 910 may not be in direct contact with the cover layer 730.

As described above with reference to FIG. 11, the first connection line 910, the crack sensing pattern 930, and the first sub-connection line 921 may be disposed in the same layer as the second conductive layer 420 of the input sensing layer 40, and the second sub-connection line 923 and the cover layer 730 may be disposed in the same layer as the first conductive layer 410 of the input sensing layer 40. For example, the first connection line 910, the crack sensing pattern 930, and the first sub-connection line 921 may each include the same material as that of the second conductive layer 420 of the input sensing layer 40, and the second sub-connection line 923 and the cover layer 730 may each include the same material as that of the first conductive layer 410 of the input sensing layer 40.

One end of the crack sensing pattern 930 may be electrically connected to the first connection line 910 via a first contact portion CNT1, and the other end of the crack sensing pattern 930 may be electrically connected to the second connection line 920 via a second contact portion CNT2. The first sub-connection line 921 of the second connection line 920 may be electrically connected to the second sub-connection line 923 via a third contact portion CNT3. As described above, the second sub-connection line 923 is electrically connected to the cover layer 730, and thus, the cover layer 730 may be electrically connected to crack sensing lines and crack sensing pads via the second sub-connection line 923 and the first sub-connection line 921.

As a comparative example, when a cover layer is electrically isolated, charges may accumulate in the cover layer, resulting in defects in a display panel due to static electricity. In embodiments of the present disclosure, because the cover layer 730 is electrically connected to any one of the connection lines of the crack sensing portion 900, a path through which charges may be discharged is provided, thereby preventing or reducing defects due to static electricity.

According to embodiments, a display panel having, in a display region, an opening around which a component may be arranged may be implemented. However, the scope of the present disclosure is not limited thereto.

It should be understood that the embodiments described herein should be considered in a descriptive sense and not for purposes of limitation. Descriptions of features or aspects within each embodiment should typically be considered as available for other similar features or aspects in other embodiments. While embodiments have been described with reference to the figures, it will be understood by those of ordinary skill in the art that various changes in form and details may be made therein without departing from the spirit and scope as defined by the following claims and their equivalents.

What is claimed is:

1. A display panel comprising:
a substrate having an opening region, a display region, and a middle region between the opening region and the display region;
a plurality of display elements in the display region;
an encapsulation layer covering the plurality of display elements and extending from the display region to the middle region;
a planarization layer in the middle region and overlapping a portion of the encapsulation layer;
a crack sensing portion on the planarization layer and extending around a portion of the opening region; and
a cover layer covering a first end of the planarization layer that is on the encapsulation layer and electrically connected to the crack sensing portion.

2. The display panel of claim 1, wherein the crack sensing portion comprises:
a first connection line and a second connection line, each extending to outside of the middle region; and
a crack sensing pattern electrically connecting the first connection line to the second connection line and adjacent to the opening region.

3. The display panel of claim 2, wherein the first connection line and the crack sensing pattern are in a first conductive layer, and
wherein the second connection line comprises a first sub-connection line in the first conductive layer and a second sub-connection line in a second conductive layer different from the first conductive layer.

4. The display panel of claim 3, wherein the cover layer is in the second conductive layer.

5. The display panel of claim 3, wherein the second sub-connection line is integrally provided with the cover layer.

6. The display panel of claim 2, wherein the crack sensing pattern has a ring shape with one side open.

7. The display panel of claim 2, wherein the crack sensing pattern comprises:
a first portion having a ring shape with one side open;
a second portion connecting one end of the first portion to the first connection line; and
a third portion connecting another end of the first portion to the second connection line.

8. The display panel of claim 1, wherein, when viewed in a direction perpendicular to the substrate, the cover layer has a closed loop shape.

9. The display panel of claim 1, wherein a groove is in the middle region and extends around the opening region, and
wherein the planarization layer covers the groove.

10. The display panel of claim 9, wherein the groove has an undercut shape.

11. A display panel comprising:
a substrate having an opening region, a display region, and a middle region between the opening region and the display region;
a plurality of display elements in the display region;
an encapsulation layer covering the plurality of display elements and extending from the display region to the middle region;
an input sensing layer on the encapsulation layer;
a planarization layer in the middle region and overlapping a portion of the encapsulation layer;
a crack sensing portion on the planarization layer and extending around a portion of the opening region; and
a cover layer covering a first end of the planarization layer that is on the encapsulation layer and electrically connected to the crack sensing portion.

12. The display panel of claim 11, wherein the input sensing layer comprises a first conductive layer, a second conductive layer, and an insulating layer between the first conductive layer and the second conductive layer, and
wherein the cover layer comprises a same material as the first conductive layer.

13. The display panel of claim 12, wherein the crack sensing portion comprises:
a first connection line and a second connection line, each extending to outside of the middle region; and
a crack sensing pattern electrically connecting the first connection line to the second connection line and adjacent to the opening region.

14. The display panel of claim 13, wherein each of the first connection line and the crack sensing pattern comprises a same material as the second conductive layer, and
wherein the second connection line comprises a first sub-connection line comprising a same material as the second conductive layer and a second sub-connection line comprising a same material as the first conductive layer.

15. The display panel of claim 14, wherein the cover layer is integrally provided with the second sub-connection line.

16. The display panel of claim 13, wherein, when viewed in a direction perpendicular to the substrate, a portion of the first connection line and a portion of the second connection line overlap the cover layer.

17. The display panel of claim 13, wherein the crack sensing pattern has a ring shape with one side open.

18. The display panel of claim 13, wherein the crack sensing pattern comprises:
a first portion having a ring shape with one side open;
a second portion connecting one end of the first portion to the first connection line; and
a third portion connecting another end of the first portion to the second connection line.

19. The display panel of claim 11, wherein, when viewed in a direction perpendicular to the substrate, the cover layer has a closed loop shape.

20. The display panel of claim 11, wherein a groove is in the middle region and extending around the opening region, and
wherein the planarization layer covers the groove.
